(19) United States
(12) Patent Application Publication
(10) Pub. No.: US 2012/0195009 A1
(43) Pub. Date: Aug. 2, 2012

(54) Electronic Product Having a Double-PCB Sandwich Structure and a Method of Assembling the Same

(75) Inventors: Martin Brueckel, Shenzhen (CN); Haixiang He, Shenzhen (CN); Wanchun Jiang, Shenzhen (CN)

(73) Assignee: OSRAM AG, Muenchen (DE)

(21) Appl. No.: 13/392,102

(22) PCT Filed: Jul. 29, 2010
(86) PCT No.: PCT/EP2010/060996

§ 371 Date: Apr. 18, 2012

(30) Foreign Application Priority Data
Aug. 25, 2009 (CN) 200910168860.5

(51) Int. Cl. H05K 7/14; H05K 3/34

(52) U.S. Cl. 361/752; 29/840

(57) ABSTRACT

An electronic product having a double-PCB sandwich structure includes a PCB assembly, and a casing having an open side. The electronic product is configured such that a protuberance is respectively formed on the inner sides of two side walls of the casing in the longitudinal direction, the PCB assembly comprises an electronic component, a base PCB and a main PCB, the length of the base PCB and the length of the main PCB in the longitudinal direction of the casing are substantially equal to each other and slightly smaller than the length of the casing so that the PCB assembly can be installed into the casing by mating with the protuberances.

### FIELD OF INVENTION

The invention relates to an electronic product having a double-PCB sandwich structure and a method of assembling the same. More specifically, the invention relates to an electronic product consisting of a casing having protuberances and a PCB assembly having a double-PCB sandwich structure, and a method of assembling a PCB assembly having a double-PCB sandwich structure into a casing having protuberances.

### BACKGROUND ART

Generally, in an electronic product, an electronic component such as a transformer is fixed to a plastic base, then the transformer is soldered to a PCB through pins of the transformer. Thus a PCB assembly consisting of a transformer, a plastic base and a PCB is formed, wherein the transformer is installed on the plastic base and soldered to the PCB through pins of the transformer and the plastic base is supported on the PCB. Then, the thus formed PCB assembly is fixed into the casing by means of screws or slots on the plastic base and so on.

However, the distance between the plastic base and the PCB must be defined properly so as to ensure proper solder penetration and to prevent noises, and to achieve the required creepage distances in some applications.

FIG. 1 shows the way of constructing a PCB assembly and a method of assembling the PCB assembly into a casing in the prior art. As shown in FIG. 1, a transformer 21 is installed on and supported by a plastic base. Pins 211 extending from the transformer 21 run through a PCB, the transformer 21 is soldered on the PCB through pins 211 to form a PCB assembly consisting of the transformer 21, the plastic base and the PCB. Then, the PCB assembly is installed on the casing by mechanical means. As shown in FIG. 1, the thickness of the plastic base is generally relatively large so as to support the transformer 21. In order to ensure a proper distance between the plastic base and the PCB, a recess is required to be formed in the lower surface of the plastic base, the thickness of the recess is the distance between the plastic base and the main PCB. However, in consideration of the thickness of the base and the manufacturing of the recess in the lower surface of the base, the material of the base needs to be plastic. However, the manufacturing of plastic base needs specialized mould, which can not be modified in size and is expensive.

### SUMMARY OF THE INVENTION

Therefore, in view of the above problems, the invention devises an electronic product having a novel double-PCB sandwich structure which adopts a base PCB instead of the plastic base in the prior art, thereby simplifying the structure and facilitating the manufacture so that the cost is reduced. Also, by utilizing the protuberances in the casing of the prior art, a PCB assembly consisting of the double-PCB sandwich structure and an electronic component can be easily installed into the casing without using any other mechanical means such as screws.

According to a first aspect of the invention, the invention provides an electronic product having a double-PCB sandwich structure, comprising a PCB assembly and a casing having an open side, wherein a protuberance is respectively formed on the inner sides of two side walls of the casing in the longitudinal direction, the PCB assembly consists of an electronic component, a base PCB and a main PCB, the length of the base PCB and the length of the main PCB in the longitudinal direction of the casing are substantially equal to each other and slightly smaller than the length of the casing so that the PCB assembly can be installed into the casing by mating with the protuberances.

According to a second aspect of the invention, the invention provides an electronic product having a double-PCB sandwich structure, wherein a first protuberance is respectively formed on the inner sides of the two side walls of the casing in the longitudinal direction, and the distance between an upper surface of the main PCB and an lower surface of the base PCB is substantially equal to the thickness of the first protuberance so that after the PCB assembly is inserted into the casing along the first protuberances, the first protuberances snap between the base PCB and the main PCB so as to install the PCB assembly into the casing

According to a third aspect of the invention, the invention provides an electronic product having a double-PCB sandwich structure, wherein a second protuberance is respectively formed under the first protuberances in parallel with the first protuberances, and the thickness of the main PCB is substantially equal to the distance between a lower surface of the first protuberances and an upper surface of the second protuberances so that after the PCB assembly is inserted into the casing, the main PCB can be supported on the upper surface of the second protuberances and snap between the first protuberances and second protuberances so as to install the PCB assembly into the casing. Preferably, the lower surface of the first protuberances and the upper surface of the second protuberances are chamfered to facilitate the insertion of the PCB assembly.

According to a fourth aspect of the invention, the invention provides a method of assembling an electronic product, the method comprising installing an electronic component on the base PCB and soldering the electronic component onto the main PCB through pins of the electronic component so as to form a PCB assembly; inserting the PCB assembly into the casing along the protuberances so that the PCB assembly can be installed into the casing by mating with the protuberances; and injection potting the casing from the open side of the casing.

According to a fifth aspect of the invention, the invention provides a method of assembling an electronic product, the method comprising installing an electronic component on the base PCB and soldering the electronic component onto the main PCB through pins of the electronic component so as to form a PCB assembly, wherein the distance between an upper surface of the main PCB and a lower surface of the base PCB is substantially equal to the thickness of the first protuberance; inserting the PCB assembly into the casing along the first protuberances so that the first protuberances snap between the base PCB and the main PCB to install the PCB assembly into the casing; and injection potting the casing from the open side of the casing.

According to a sixth aspect of the invention, the invention provides a method of assembling an electronic product, the method comprising installing an electronic component on the base PCB and soldering the electronic component onto the main PCB through pins of the electronic component so as to form a PCB assembly, wherein the distance between an upper surface of the main PCB and a lower surface of the base PCB is substantially equal to the thickness of the first protuberances and the thickness of the main PCB is substantially equal to the distance between a lower surface of the first protuberances and an upper surface of the second protuberances; inserting the main PCB into the casing along the first protuberances and the second protuberances so that the main PCB is supported on an upper surface of the second protuberances and snaps between the first protuberances and the second protuberances so as to install the PCB assembly into the casing; and injection potting the casing from the open side of the casing. Preferably, the lower surface of the first protuberances and the upper surface of the second protuberances are chamfered to facilitate the insertion of the PCB assembly.

### BRIEF DESCRIPTION OF THE DRAWINGS

The invention will be more fully understood from the detailed description of the preferred and non-limiting embodiments of the invention when taken in conjunction with the drawing, in which:

FIG. 1 shows a PCB assembly having an electronic component (shown as a transformer 21 in the description) in the prior art, wherein a plastic base, a PCB, a transformer 21 and pins thereof are shown;

FIG. 2 is a perspective view of a casing having a protuberance and used in the embodiments of the invention;

FIG. 3 is a front view of the casing;

FIG. 4 is a top view of the casing;

FIG. 5 is a cross-sectional view of the casing taken along the line A-A in FIG. 4;

FIG. 6a is an enlarged view of part B in FIG. 5, showing the details of the protuberance;

FIG. 6b is an enlarged view of part D in FIG. 3, showing the details of the protuberance;

FIG. 7 is a schematic view showing the PCB assembly and the casing are assembled together according to a first embodiment of the invention; and

FIG. 8 is a schematic view showing the PCB assembly and the casing are assembled together according to a second embodiment of the invention.

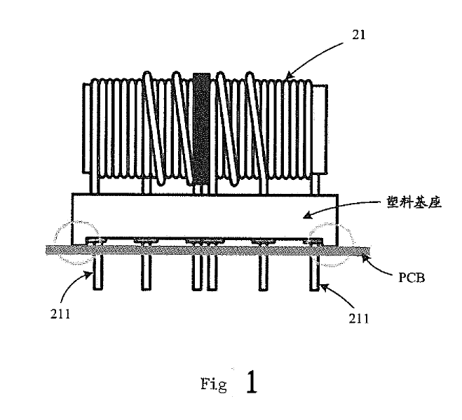

### DETAILED DESCRIPTION OF EMBODIMENTS

Firstly, a casing used in the invention will be described with reference to FIGS. 2-6. As shown in FIG. 2, the casing used in the invention is generally designated at 1. In the following description, the left and right direction of the plane of FIG. 7 is defined as the longitudinal direction of the casing 1, i.e., the lengthwise direction. The up and down direction of the plane of FIG. 7 is defined as the up and down direction of the casing 1, i.e., the height direction.

As shown in FIG. 2, casing 1 is generally formed into a hollow rectangular parallelepiped configuration to form an internal space therein and has an open side for facilitating the insertion of a PCB assembly into the casing and receipt of the PCB assembly inside the internal space, as will be described later. Two through holes are shown on the top wall 11 of the casing for wiring of electronic components of the PCB assembly. The casing 1 is generally formed integrally from plastic material.

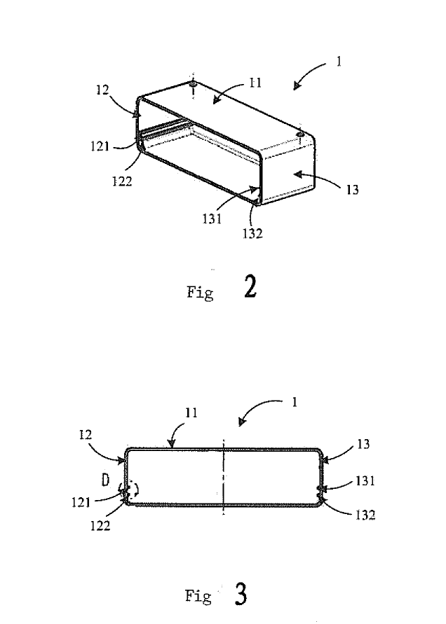

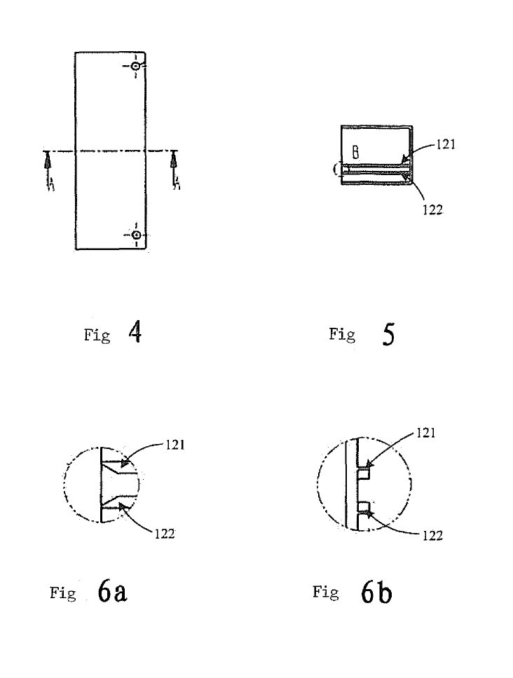

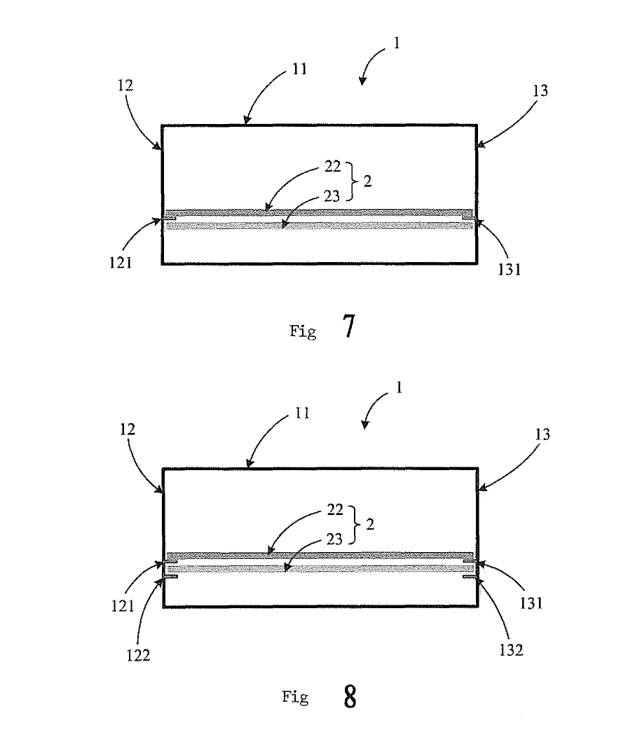

As can be seen from FIG. 2, a first protuberance 121 and 131 is respectively formed on the inner side of the two side walls 12, 13 of the casing 1 in the longitudinal direction. Optionally, a second protuberance 122 and 132 is respectively formed under the first protuberance 121 and 122 in parallel with the first protuberance 121 and 131. The protuberances 121, 122 are formed symmetrically with the protuberances 131, 132 inside the internal space, namely, the first protuberance 121 is located at the same height as the first protuberance 131, the second protuberance 122 is located at the same height as the second protuberance 132. The protuberances may be formed integrally with the casing 1. Now turn to FIGS. 6a and 6b, which respectively show part B in FIG. 5 and part D in FIG. 3 in enlarged view. As can be seen in FIG. 6a, the lower surface of the first protuberance 121, 131 and the upper surface of the second protuberance 122, 132 are chamfered so as to facilitate the insertion and withdrawal of the PCB assembly.

Now, the PCB assembly 2 and casing 1 according to a first embodiment of the invention will be described with reference to FIG. 7, which is a schematic view showing the PCB 2 assembly and the casing 1 assembled together according to a first embodiment of the invention. For the sake of simplicity, the transformer 21 is not shown in FIG. 7. In the casing used in the embodiment, a first protuberance is respectively formed on the inner side of the side walls on both ends of the casing in the longitudinal direction, i.e., a first protuberance 121 and 131. In the case of this embodiment, the distance between the upper surface of the main PCB 23 and the lower surface of the base PCB 22 is set substantially equal to the thickness of the first protuberance, so that upon sliding of the PCB assembly 2 into the casing 1 along the first protuberances (the upper surface of the main PCB 23 contacts the lower surface of the protuberance, and the lower surface of the base PCB 22 contacts the upper surface of the first protuberance), the PCB assembly 2 snaps onto the first protuberances so as to be fixed, thus limiting the movement of PCB assembly 2 in the up and down direction of the casing.

The method of assembling the PCB assembly 2 into the casing 1 according to the first embodiment of the invention will be described hereinafter. The casing 1 has a first protuberance 121 and 131 on the inner side of the side walls on both ends of the casing 1 in the longitudinal direction. The method comprises: installing the transformer 21 onto the base PCB 22, and soldering the transformer 21 onto the main PCB 23 through the pins of the transformer 21 to form a PCB assembly 2, wherein the distance between the upper surface of the main PCB 23 and the lower surface of the base PCB 22 is substantially equal to the thickness of the first protuberances; inserting the PCB assembly 2 into the casing 1 along the first protuberances, so that the first protuberances snap between the base PCB 22 and the main PCB 23 to install the PCB assembly 2 inside the casing 1; and injection potting the casing from the open side of the casing.

Now, the PCB assembly 2 and casing 1 according to a second embodiment of the invention will be described with reference to FIG. 8, which is a schematic view showing the PCB assembly 2 and the casing 1 assembled together according to a second embodiment of the invention. In this embodiment, a second protuberance 122, 132 is respectively provided under the first protuberance 121, 131 in parallel with the first protuberance 121, 131, and the thickness of the main PCB 23 is substantially equal to the distance between the lower surface of the first protuberance and the upper surface of the second protuberance, so that upon insertion of the PCB assembly 2 into the casing 1, the main PCB 23 can be supported on the upper surface of the second protuberance and snaps between the first protuberances and the second protuberances to install the PCB assembly 2 inside the casing 1.

The method of assembling the PCB assembly 2 into the casing 1 according to the second embodiment of the invention will be described hereinafter. A second protuberance 122, 132 is respectively provided under the first protuberance 121, 131 in parallel with the first protuberance 121, 131. The method comprises: installing the transformer 21 onto the base PCB 22, and soldering the transformer 21 onto the main PCB 23 through the pins of the transformer 21 to form a PCB assembly 2, wherein the distance between the upper surface of the main PCB 23 and the lower surface of the base PCB 22 is substantially equal to the thickness of the first protuberance, and the thickness of the main PCB is substantially equal to the distance between the lower surface of the first protuberance and the upper surface of the second protuberance; inserting the main PCB 23 into the casing 1 along the first protuberances and the second protuberances, so that the main PCB 23 can be supported on the upper surface of the second protuberances and snaps between the first protuberances and the second protuberances to install the PCB assembly 2 inside the casing 1; and injection potting the casing from the open side of the casing.

While the preferred embodiments of the casing are described herein, it is understood by those skilled in the art that various variations and modifications can be made to the casing without departing the spirit and scope of the invention. For example, the size, shape, structure and number can be appropriately modified, as long as the protuberances can properly mate with the PCB assembly. In addition, while a transformer is used in the description as an example of the electronic components to describe the invention, not limited to this, any other electronic component may be used to form a PCB assembly having a double-PCB assembly structure without departing the scope of the invention. The scope of protection is defined by the appended claims.

1. An electronic product having a double-PCB sandwich structure, comprising
a PCB assembly; and
a casing having an open side,
wherein a protuberance is respectively formed on the inner sides of two side walls of the casing in the longitudinal direction, the PCB assembly comprises an electronic component, a base PCB and a main PCB, the length of the base PCB and the length of the main PCB in the longitudinal direction of the casing are substantially equal to each other and slightly smaller than the length of the casing so that the PCB assembly can be installed into the casing by mating with the protuberances.

2. An electronic product according to claim 1, wherein a first protuberance is respectively formed on the inner sides of the two side walls of the casing in the longitudinal direction, and the distance between an upper surface of the main PCB and an lower surface of the base PCB is substantially equal to the thickness of the first protuberance so that upon insertion of the PCB assembly into the casing along the first protuberances, the first protuberances snap between the base PCB and the main PCB so as to install the PCB assembly into the casing.

3. An electronic product according to claim 2, wherein a second protuberance is respectively formed under the first protuberances in parallel with the first protuberances, and the thickness of the main PCB is substantially equal to the distance between a lower surface of the first protuberances and an upper surface of the second protuberances so that upon insertion of the PCB assembly into the casing, the main PCB can be supported on the upper surface of the second protuberances and snap between the first protuberances and second protuberances so as to install the PCB assembly into the casing.

4. An electronic product according to claim 3, wherein the lower surface of the first protuberances and the upper surface of the second protuberances are chamfered to facilitate the insertion of the PCB assembly.

5. A method of assembling an electronic product according to claim 1, comprising:
installing an electronic component on the base PCB and soldering the electronic component onto the main PCB through pins of the electronic component so as to form a PCB assembly;
inserting the PCB assembly into the casing along the protuberances so that the PCB assembly can be installed into the casing by mating with the protuberances; and
injection potting the casing from the open side of the casing.

6. A method of assembling an electronic product according to claim 2, comprising:
installing an electronic component on the base PCB and soldering the electronic component onto the main PCB through pins of the electronic component so as to form a PCB assembly, wherein the distance between an upper surface of the main PCB and a lower surface of the base PCB is substantially equal to the thickness of the first protuberance;
inserting the PCB assembly into the casing along the first protuberances so that the first protuberances snap between the base PCB and the main PCB to install the PCB assembly into the casing; and
injection potting the casing from the open side of the casing.

7. A method of assembling an electronic product according to claim 3, comprising:
installing an electronic component on the base PCB and soldering the electronic component onto the main PCB through pins of the electronic component so as to form a PCB assembly, wherein the distance between an upper surface of the main PCB and a lower surface of the base PCB is substantially equal to the thickness of the first protuberances and the thickness of the main PCB is substantially equal to the distance between a lower surface of the first protuberances and an upper surface of the second protuberances;
inserting the main PCB into the casing along the first protuberances and the second protuberances so that the main PCB is supported on an upper surface of the second protuberances and snaps between the first protuberances and the second protuberances so as to install the PCB assembly into the casing; and
injection potting the casing from the open side of the casing.

8. A method according to claim 7, wherein the lower surface of the first protuberances and the upper surface of the second protuberances are chamfered to facilitate the insertion of the PCB assembly.
